(19) United States
(12) Patent Application Publication
(10) Pub. No.: US 2014/0145226 A1
(43) Pub. Date: May 29, 2014

(54) POLYMER COMPOSITE, USE OF THE POLYMER COMPOSITE AND OPTOELECTRONIC COMPONENT CONTAINING THE POLYMER COMPOSITE

(71) Applicant: Klaus Höhn, Forchheim (DE)

(72) Inventor: Klaus Höhn, Forchheim (DE)

(73) Assignee: OSRAM Opto Semiconductors GmbH, Regensburg (DE)

(21) Appl. No.: 13/818,484

(22) PCT Filed: Aug. 23, 2011
(86) PCT No.: PCT/EP2011/064448

§ 371 Date: May 1, 2013

(30) Foreign Application Priority Data
Aug. 23, 2010 (DE) 10 2010 035 110.5

(51) Int. Cl. H01L 33/56; H01L 33/36; H01L 33/60

(52) U.S. Cl. CPC H01L 33/56; H01L 33/60; H01L 33/36
USPC 257/98; 252/181.3

(57) ABSTRACT

A polymer composite includes a polymer matrix and ZnO particles distributed in the polymer matrix, wherein the polymer composite is a barrier for compounds containing sulfur.

### RELATED APPLICATIONS

This is a §371 of International Application No. PCT/EP2011/064448, with an international filing date of Aug. 23, 2011 (WO 2012/025518 A1, published Mar. 1, 2012), which is based on German Patent Application No. 10 2010 035 110.5, filed Aug. 23, 2010, the subject matter of which is incorporated herein by reference.

### TECHNICAL FIELD

This disclosure relates to a polymer composite as well as its use and an optoelectronic component containing the polymer composite.

### BACKGROUND

There is a need to provide a polymer composite which has improved stability.

### SUMMARY

I provide a polymer composite including a polymer matrix and ZnO particles distributed in the polymer matrix, wherein the polymer composite is a barrier for compounds containing sulfur.

I also provide a housing material, functional material or fastening material including the polymer composite.

I further provide an electrically conductive adhesive including the polymer composite.

I further yet provide an optoelectronic component including a substrate, a radiation-emitting element on the substrate, the element being contacted by a first and a second electrical contact and being laterally enclosed by a housing, and an encapsulation over the element and at least between the element and the housing, the encapsulation and/or the housing containing the polymer composite.

I still further provide an LED including the optoelectronic component.

### BRIEF DESCRIPTION OF THE DRAWING

FIG. 1 is a schematic side view of an LED.

### DETAILED DESCRIPTION

I provide a polymer composite which contains a polymer matrix and ZnO particles distributed in the polymer matrix. The polymer composite is a barrier for compounds containing sulfur. A polymer composite is therefore provided which is stable in relation to compounds containing sulfur, for example, harmful gases containing sulfur such as H₂S or SOₓ, that is to say it has reduced or zero permeability for such gases or compounds.

Optoelectronic components such as LEDs which have an encapsulation may be exposed to degassing of additives containing sulfur, for example, of rubber seals, which together with air humidity in conjunction with the radiation emitted by the LED, can lead to electrical and optical functional perturbations. This may be due to moisture- and gas-permeability of the encapsulation material. When compounds containing sulfur penetrate through the encapsulation, corrosion phenomena may, for example, occur on the electrical contacts of the LED. Furthermore, reflective properties on metallic optical reflectors of the LED, for example, Ag reflectors, may be degraded. This is caused by formation of dark-matt or black Ag(I) and/or Ag(II) sulfide surfaces. Such perturbation can crucially impair the optical quality of an LED. Furthermore, compounds containing sulfur can lead to perturbing deposits on surfaces of light-emitting chips which reduce the light intensity or brightness or modify the emission characteristic, both of which can lead to limited lifetimes of the component.

By the use of my polymer composite as an encapsulation material, the encapsulation is stabilized in relation to the compounds containing sulfur so that the aforementioned degradation of the component can be reduced or prevented.

In a similar way to the mechanisms mentioned in relation to the encapsulation, compounds containing sulfur can also lead to sulfur deposits and/or corrosion phenomena in electrically conductive adhesives which contain noble metal particles, for example, Ag or Au when they penetrate into these adhesives. Such electrically conductive adhesives may, for example, be used in the fastening of LEDs on printed circuit boards or for fastening epitaxial layers on substrates. Corrosion phenomena in adhesive layers used in the field of optoelectronic components are also undesirable since, on the one hand, they have an esthetically detrimental effect and/or can reduce the optical quality and, on the other hand, can reduce electrical conductivity of the electrically conductive adhesive, which in turn leads to degraded function or failure of the optoelectronic component.

Use of a polymer composite in an electrically conductive adhesive can reduce or prevent such corrosion phenomena and therefore preserve its function, in particular its electrical conductivity.

The polymer matrix of the polymer composite may be selected from a group which consists of silicones, silicone hybrids, thermosets and thermoplastics. Acrylates, polycarbonates, polyesters, polyamides, polyurethanes or epoxides or epoxy resins may, for example, be used as the polymer matrix. The polymer matrix may contain additively crosslinked silicones.

The ZnO particles may be added to silicones. Additively crosslinking silicones may be used in this case. To produce such a polymer composite, the ZnO particles are added to the silicone then thermally cured together, the silicone becoming crosslinked. Permeability of the silicone for harmful gases or moisture can be reduced by the addition of the ZnO particles.

The ZnO particles may be present in the polymer matrix with a content of 0.01 to 10 wt %, preferably 0.01 to 0.5 wt %. ZnO particles which have a purity of more than 95%, preferably more than 98%, may be used.

The ZnO particles may have a particle size of 3 to 100 nm. For example, the range may be 3 to 50 nm. ZnO particles which are nanoparticles are thus added to the polymer composite. Distribution of the ZnO particles in the matrix may be agglomerate- and/or aggregation-free. The ZnO particles are thus present as individual particles in the polymer matrix so that transparency of the polymer matrix is preserved.

The ZnO particles may chemically bind sulfur. For example, ZnS may be formed from ZnO upon contact with gases containing sulfur. ZnS has a low solubility. Therefore, ZnO can contribute to the harmful gases containing sulfur being purified and compounds containing sulfur can no longer penetrate through the polymer composite.

In this way, for example, the ageing behavior of optoelectronic components and modules can be improved. Owing to the nanoscale size of the ZnO particles added, they have a large surface area, which can have a positive effect on the purification of the gases containing sulfur.

Furthermore, the optical properties and transparency of the polymer composite can be preserved owing to the small size as well as the agglomerate- and/or aggregation-free distribution of the ZnO particles. The polymer composite may, for example, be transparent for radiation with a wavelength >410 nm. It may furthermore absorb radiation with a wavelength <410 nm. For example, the polymer composite may therefore be used as a filter.

The polymer composite may have an application form selected from a group which consists of casting, molding, adhesive bonding, coating, painting and extrusion. The polymer composite can therefore be applied and/or shaped in accordance with the intended use.

The use of a polymer composite according to the properties mentioned above as a housing material, functional material or fastening material is furthermore provided.

If the polymer composite is used as a fastening material, it may, for example, be added to paints or adhesives. Such a paint may, for example, be added to improve the resistance of PCBs (printed circuit boards) to media and harmful gases.

The polymer composite may be used as a fastening material which is an electrically conductive adhesive. Besides a polymer composite, an electrically conductive adhesive of this type may furthermore contain metal particles. The metal particles may be selected from a group which contains Ag particles, Au particles, Ni particles and Pd particles. In particular, Ag particles or Au particles may be selected. The proportion of the metal particles may in this case be more than 70 wt %, in particular 80 to 90 wt % in the polymer composite.

The rheological properties of the electrically conductive adhesive can be adjusted by the polymer matrix so that they correspond entirely or at least substantially to those of conventional electrically conductive adhesives which do not contain ZnO particles. For example, a low viscosity of the electrically conductive adhesive may thus be adjusted. This, for example, allows straightforward application of the adhesive.

Bonding agents may furthermore be added to electrically conductive adhesives. These can improve the adhesive properties and, for example, comprise silanes. Furthermore, electrically conductive adhesives may contain wetting agents. These, however, should be added only in a proportion which does not affect the adhesive properties of the electrically conductive adhesive. In addition or as an alternative, according to requirements, the wetting behavior of an electrically conductive adhesive may be adjusted by surface methods on an applied adhesive layer.

The ZnO particles in the electrically conductive adhesive purify harmful gases containing sulfur present in the vicinity of the adhesive which, for example, fastens an optoelectronic component on a supply lead, for example, a supply lead in a housing or on a printed circuit board or an epitaxial layer on a substrate. The electrically conductive adhesive therefore has little or no permeability for moisture and harmful gases containing sulfur. This prevents sulfide surfaces, for example, dark-matt or black Ag(I) and/or Ag(II) sulfide surfaces, from being able to form on the metal particles, in particular on Ag or Au particles distributed in the adhesive, by reaction with compounds containing sulfur. It furthermore prevents the electrical conductive metal particles from corroding because of compounds containing sulfur.

By using the polymer composite in the electrically conductive adhesive, degradation of the adhesive can thus be prevented or reduced and the lifetime of the optoelectronic component, on or in which it is applied, can therefore be extended.

When employing the polymer composite as a functional material, it may, for example, be shaped to form packaging films. If the polymer composite is employed as a functional material, it may, for example, be used as an encapsulation material or potting material in photovoltaic and solar technology, medical technology, optics and optoelectronic products.

For example, the polymer composite may be used to produce optical elements such as lenses or prisms.

Optoelectronic components which contain a polymer composite according to the properties mentioned above may, for example, be used in the automotive field, general lighting, industrial applications and entertainment electronics. Luminescent media may furthermore be added to the polymer composite, and function therein as a filter.

An optoelectronic component is furthermore provided which comprises a substrate, a radiation-emitting element on the substrate and an encapsulation. The radiation-emitting element contacts a first and a second electrical contact and is laterally enclosed by a housing. The encapsulation is arranged over the element and at least between the element and the housing, the encapsulation and/or the housing contains a polymer composite according to one of the examples mentioned above.

The encapsulation and/or the housing may be transparent for the radiation emitted by the radiation-emitting element.

The encapsulation and/or the housing which contain a polymer composite according to the properties mentioned above, may seal the radiation-emitting element and the electrical contacts against compounds containing sulfur.

The housing of the optoelectronic component may have reflective inner surfaces which face toward the radiation-emitting element and are sealed against compounds containing sulfur by the encapsulation.

The optoelectronic component may be an LED. The LED may, for example, be an LED which emits white light.

Owing to the fact that the optoelectronic component comprises a polymer composite which contains ZnO particles in its encapsulation and/or in its housing, its lifetime and light intensity or brightness as well as emission characteristic can be improved.

The ZnO particles purify harmful gases containing sulfur which are, for example, present at a level of about 100 ppm in the vicinity of the optoelectronic component, for example, the LED. The encapsulation compound and/or the housing material is therefore less permeable for moisture and harmful gases containing sulfur which can no longer penetrate through the encapsulation and/or the housing to the radiation-emitting element, the contacts and the inner wall of the housing. This prevents dark-matt or black Ag(I) and/or Ag(II) sulfide surfaces, for example, from being able to form by reaction with compounds containing sulfur on the inner walls of the housing which may be used as optical reflectors, and the reflection at the inner walls of the housing is preserved.

It furthermore prevents the electrical contacts from exhibiting corrosion owing to external influences, for example, compounds containing sulfur. By use of the polymer composite in the encapsulation and/or in the housing, both the electrical and optical functions of an optoelectronic component can thus be substantially preserved and its lifetime therefore extended.

My polymer composite and components will be explained in more detail in an example with the aid of the Drawing.

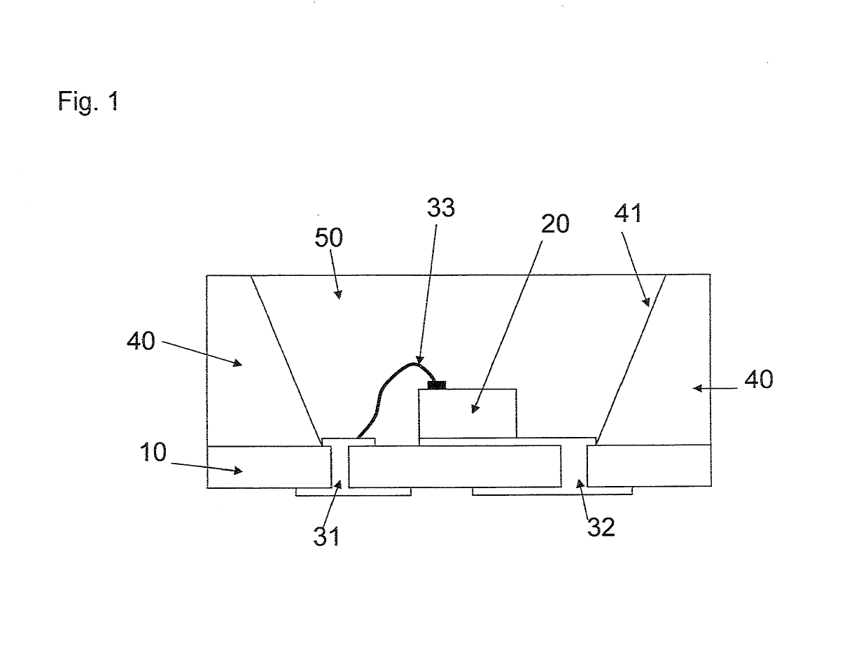

FIG. 1 shows a schematic side view of an optoelectronic component with reference to the example of an LED. It comprises a substrate 10 which has through-contacts, through which a first electrical contact 31 and a second electrical contact 32 respectively pass. Arranged on the second contact 32, there is a radiation-emitting element 20 that leads via a bonding wire 33 which is fastened on the surface of the element 20 facing away from the substrate, to the first contact 31. Arranged around the radiation-emitting element 20, there is a housing 40 which has oblique inner walls 41 to improve reflection of the emitted radiation. The encapsulation 50, which encloses the radiation-emitting element 20 as well as the contacts 31, 32 and the bonding wire 33, lies inside the housing 40. The encapsulation 50 and/or the housing 40 contain a polymer composite which comprises a polymer matrix and ZnO particles. For example, the polymer matrix may contain a silicone, in particular an additively crosslinked silicone. The ZnO particles may have a particle size of 3 to 50 nm so that they are nanoscale particles. Furthermore, the particles may have a purity of more than 98% and are present in the polymer matrix with a content of 0.01 to 10 wt %.

The encapsulation 50 and/or the housing 40 therefore seal both the radiation-emitting element 20 and the contacts 31 and 32 as well as the inner walls of the housing 41 against external influences. For example, moisture and compounds containing sulfur cannot penetrate through the encapsulation 50 since, from the ZnO particles present therein and the compounds containing sulfur, ZnS compounds are, for example, formed in the encapsulation 50 which have a low solubility and cannot penetrate to the sensitive components such as the radiation-emitting element 20, the contacts 31 and 32 and the inner walls 41 of the housing.

Corrosion therefore does not take place on the contacts 31 and 32, and the inner walls 41 of the housing as well as the surface of the radiation-emitting element 20 remain free of any discolorations due to compounds containing sulfur, which may occur owing to reaction of sulfur with the materials of the housing 40 or of the radiation-emitting element 20. The optical property and the brightness of the optoelectronic component are therefore preserved. The component can operate reliably and has an improved operating lifetime owing to the stabilization of the encapsulation and/or of the housing against compounds containing sulfur. As a result of the fact that corrosion of the contacts 31 and 32 is also prevented, the electrical properties of the component are also preserved.

Application forms of the polymer composite are, for example, casting, molding, adhesive bonding, coating, painting or extrusion. These application forms may also be employed for the potting, mounting and coating of LEDs. For example, electrically conductive particles such as Ag or Au particles may be added to the polymer composite, which can therefore be employed as an electrically conductive adhesive. The electrically conductive adhesive may be used for chip mounting.

The polymer composite acts as a stabilizer against compounds containing sulfur and is an economical solution to increase the operating lifetime of many components which, for example, comprise an encapsulation that contains this polymer composite.

My polymer composite and components are not restricted to the examples mentioned above, but also permits combinations of features which are not specifically indicated in the appended claims or the description.

1. A polymer composite comprising:
a polymer matrix and
ZnO particles distributed in the polymer matrix,
wherein the polymer composite is a barrier for compounds containing sulfur.

2. The polymer composite according to claim 1, wherein the polymer matrix comprises at least one of silicones, silicone hybrids, thermosets and thermoplastics.

3. The polymer composite according to claim 1, wherein the ZnO particles are present in the polymer matrix in an amount of 0.01 to 10 wt %.

4. The polymer composite according to claim 1, wherein the ZnO particles have a particle size of 3 to 100 nm.

5. The polymer composite according to claim 1, wherein distribution of the ZnO particles in the polymer matrix is agglomerate- and/or aggregation-free.

6. The polymer composite according to claim 1, wherein the ZnO particles chemically bind sulfur.

7. The polymer composite according to claim 1, which is transparent for radiation with a wavelength >410 nm.

8. The polymer composite according to claim 1 is in a form selected from a group consisting of casting, molding, adhesive bonding, coating, painting, and extrusion.

9. A housing material, functional material or fastening material comprising the polymer composite according to claim 1.

10. An electrically conductive adhesive comprising the polymer composite according to claim 1.

11. An optoelectronic component comprising:
a substrate,
a radiation-emitting element on the substrate, the element being contacted by a first and a second electrical contact and being laterally enclosed by a housing, and
an encapsulation over the element and at least between the element and the housing, the encapsulation and/or the housing containing a polymer composite according to claim 1.

12. The optoelectronic component according to claim 1, wherein the encapsulation and/or the housing are transparent emitted radiation.

13. The optoelectronic component according to claim 11, wherein the radiation-emitting element and the first and second electrical contacts are sealed against compounds containing sulfur by the encapsulation and/or the housing.

14. The optoelectronic component according to claim 11, wherein the housing has reflective inner surfaces facing the radiation-emitting element and are sealed against compounds containing sulfur by the encapsulation.

15. An LED comprising the optoelectronic component according to claim 11.

16. The polymer composite according to claim 2, wherein the polymer matrix is selected from the group consisting of thermosets and thermoplastics.
